(19) United States
(12) Patent Application Publication
(10) Pub. No.: US 2012/0006377 A1
(43) Pub. Date: Jan. 12, 2012

(54) PHOTOELECTRIC CONVERSION MODULE

(75) Inventors: Hyun-Chul Kim, Yongin-si (KR); Sang-Yeol Hur, Yongin-si (KR); Joo-Sik Jung, Yongin-si (KR)

(73) Assignee: Samsung SDI Co., Ltd., Yongin-si (KR)

(21) Appl. No.: 12/912,568

(22) Filed: Oct. 26, 2010

Related U.S. Application Data
(60) Provisional application No. 61/363,588, filed on Jul. 12, 2010.

(51) Int. Cl. H01L 31/042

(52) U.S. Cl. 136/244

(57) ABSTRACT

A photoelectric conversion module is disclosed. The photoelectric conversion module includes a light receiving substrate and a counter substrate facing each other and a first unit photoelectric cell and a second unit photoelectric cell formed between the light receiving substrate and the counter substrate. The first unit photoelectric cell includes a first optical electrode formed on the light receiving substrate and a first counter electrode formed on the counter substrate, a second unit photoelectric cell including a second optical electrode formed on the counter substrate and a second counter electrode formed on the light receiving substrate. The first optical electrode includes a first semiconductor layer, the second optical electrode includes a second semiconductor layer and a first width of the first semiconductor layer is asymmetric to a second width of the second semiconductor layer.

### CROSS-REFERENCE TO RELATED APPLICATIONS

This application is a non-provisional application that claims priority to and the benefit of U.S. application Ser. No. 61/363,588, filed on Jul. 12, 2010, which is hereby incorporated by reference in its entirety.

### BACKGROUND

1. Field of the Disclosure

The disclosed technology relates to a photoelectric conversion module, and more particularly, to a photoelectric conversion module having varying widths of optical electrodes formed on a substrate.

2. Description of the Related Technology

In general, photoelectric conversion modules convert optical energy into electric energy and may include, for example, solar cells. General solar cells are wafer-type silicon or crystalline solar cells using a p-n semiconductor junction. However, semiconductor materials used to form silicon solar cells are often of high-purity and thus manufacturing cost is high. Unlike silicon solar cells, dye-sensitized solar cells (DSSC) include photosensitive dye, a semiconductor material and an electrolyte. The photosensitive dye generates excited electrons when visible light is incident thereon, the semiconductor material receives the excited electrons and the electrolyte reacts with the electrons via an external circuit. DSSC may have significantly higher photoelectric conversion efficiency than silicon solar cells. Thus, DSSC are considered next generation solar cells.

### SUMMARY OF CERTAIN INVENTIVE ASPECTS

In one aspect, a photoelectric conversion module is provided, which has improved electricity generation efficiency of a solar cell by forming widths of a plurality of optical electrodes formed on a substrate to be asymmetric with each other.

In another aspect, a photoelectric conversion module includes, for example, a light receiving substrate and a counter substrate facing each other and a first unit photoelectric cell and a second unit photoelectric cell formed between the light receiving substrate and the counter substrate.

In some embodiments, the first unit photoelectric cell includes a first optical electrode formed on the light receiving substrate and a first counter electrode formed on the counter substrate. In some embodiments, a second unit photoelectric cell includes a second optical electrode formed on the counter substrate and a second counter electrode formed on the light receiving substrate. In some embodiments, the first optical electrode includes a first semiconductor layer.

In some embodiments, the second optical electrode includes a second semiconductor layer. In some embodiments, a first width of the first semiconductor layer is asymmetric to a second width of the second semiconductor layer. In some embodiments, a first electrolyte layer is positioned between the first optical electrode and the first counter electrode. In some embodiments, a second electrolyte layer is positioned between the second optical electrode and the second counter electrode. In some embodiments, the first optical electrode further includes a first transparent conductive film.

In some embodiments, the first counter electrode includes, for example, a second transparent conductive film and a first catalyst layer. In some embodiments, the second optical electrode further includes, for example, a third transparent conductive film. In some embodiments, the second counter electrode includes, for example, a fourth transparent conductive film and a second catalyst layer. In some embodiments, the first transparent conductive film, the second transparent conductive film, the third transparent conductive film and the fourth transparent conductive film are electrically connected to leads. In some embodiments, the first width is less than the second width. In some embodiments, the second width is less than about twice the first width. In some embodiments, the second width is less than the first width.

In some embodiments, the first width is less than about twice the second width. In some embodiments, the first width and the second width are measured in a direction substantially parallel to the surface of the light receiving substrate and the counter substrate, respectively. In some embodiments, a first height of the first semiconductor layer is asymmetric to a second height of the second semiconductor layer. In some embodiments, the first height is measured in a direction substantially normal to the surface of the light receiving substrate and wherein the second height is measured in a direction substantially normal to the surface of the counter substrate. In some embodiments, the first unit photoelectric cell and the second unit photoelectric cell are separated by a sealant. In some embodiments, the sealant includes, for example, a first scribe line.

In another aspect, a photoelectric conversion module includes, for example, a light receiving substrate and a counter substrate facing each other and a first unit photoelectric cell and a second unit photoelectric cell formed between the light receiving substrate and the counter substrate. In some embodiments, the first unit photoelectric cell includes a first optical electrode formed on the light receiving substrate and a first counter electrode formed on the counter substrate. In some embodiments, a second unit photoelectric cell includes, for example, a second optical electrode formed on the counter substrate and a second counter electrode formed on the light receiving substrate. In some embodiments, the first optical electrode includes a first semiconductor layer. In some embodiments, the second optical electrode includes a second semiconductor layer. In some embodiments, a first height of the first semiconductor layer is asymmetric to a second height of the second semiconductor layer. In some embodiments, the first height is measured in a direction substantially normal to the surface of the light receiving substrate. In some embodiments, the second height is measured in a direction substantially normal to the surface of the counter substrate.

In some embodiments, the first optical electrode of the first unit photoelectric cell and second counter electrode of the second unit photoelectric cell are alternately arranged on the light receiving substrate, wherein the first counter electrode of the first unit photoelectric cell and second optical electrodes of the second unit photoelectric cells are alternately arranged on the counter substrate, and the first counter electrode of the first unit photoelectric cells and the second optical electrode of the second unit photoelectric cells arranged on the counter substrate are formed to face the first optical electrode of the first unit photoelectric cell and the second counter electrode of the second unit photoelectric cell arranged on the light receiving substrate, respectively, in a perpendicular direction to the surface of the light receiving substrate and the surface of the counter substrate.

In some embodiments, the first optical electrode includes, for example, a first transparent conductive film, wherein the first counter electrode includes, for example, a second transparent conductive film, wherein the second optical electrode includes, for example, a third transparent conductive film, and wherein the second counter electrode includes, for example, a fourth transparent conductive film.

In some embodiments, the first transparent conductive film and the fourth transparent conductive film are electrically connected to each other on the light receiving substrate, and wherein the first transparent conductive film and the fourth transparent conductive film are separated from each other by a first scribe line between a pair of the first and the second unit photoelectric cells and another adjacent pair of the first and the second unit photoelectric cells.

In some embodiments, the second transparent conductive film and the third transparent conductive film are electrically connected to each other on the counter substrate to respectively alternate with the first transparent conductive film and the fourth transparent conductive film, and the second transparent conductive film and the third transparent conductive film are separated from each other by a second scribe line between the pair of the first and the second unit photoelectric cells and the another adjacent pair of the first and the second unit photoelectric cells. In some embodiments, the first height is less than the second height.

In another aspect, a solar cell including a photoelectric conversion module is provided.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus, system or method according to some of the described embodiments can have several aspects, no single one of which necessarily is solely responsible for the desirable attributes of the apparatus, system or method. After considering this discussion, and particularly after reading the section entitled “Detailed Description of Certain Inventive Embodiments” one will understand how illustrated features serve to explain certain principles of the present disclosure.

FIG. 1 is a cross-sectional view of a photoelectric conversion module according to an embodiment of the present disclosure.

FIG. 2A is a plan view of a light receiving substrate of the photoelectric conversion module of FIG. 1.

FIG. 2B is a plan view of a counter substrate of the photoelectric conversion module of FIG. 1.

FIG. 3 is a graph showing electricity generation efficiency of the photoelectric conversion module of FIG. 1.

FIG. 4 is a cross-sectional view of a photoelectric conversion module according to another embodiment of the present disclosure.

### DETAILED DESCRIPTION OF CERTAIN INVENTIVE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements. Certain embodiments will be described in more detail with reference to the accompanying drawings, so that a person having ordinary skill in the art can readily make and use aspects of the present disclosure.

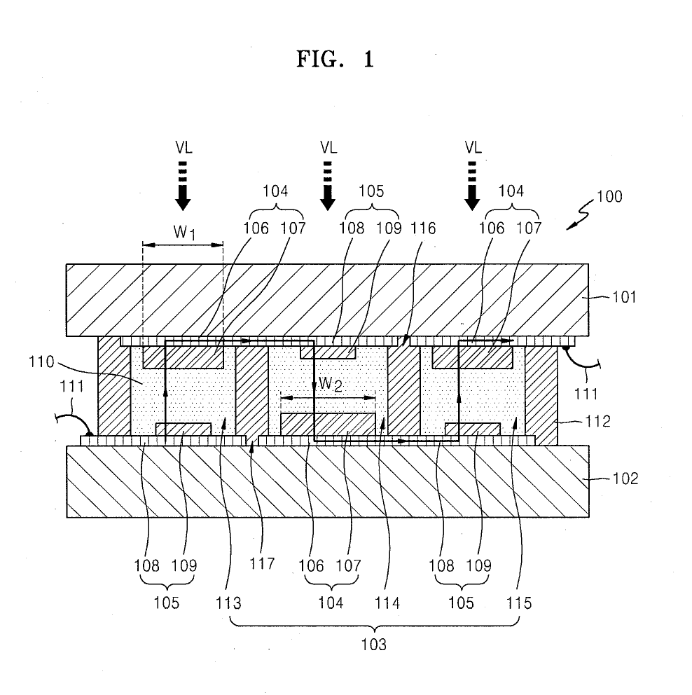

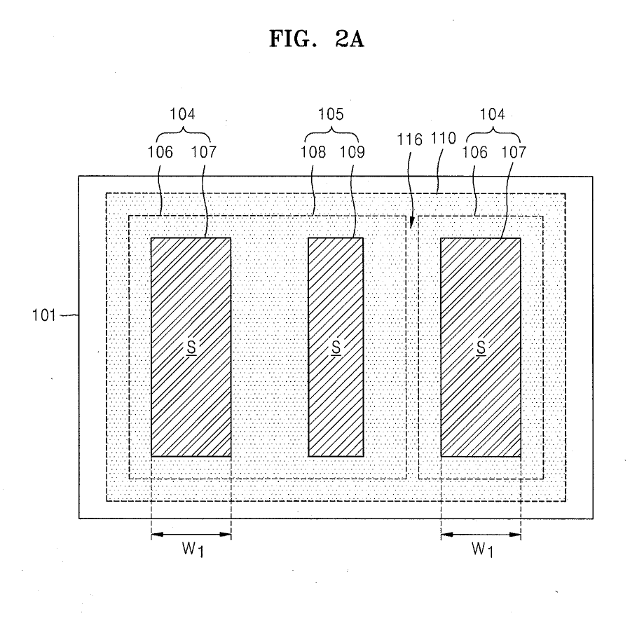

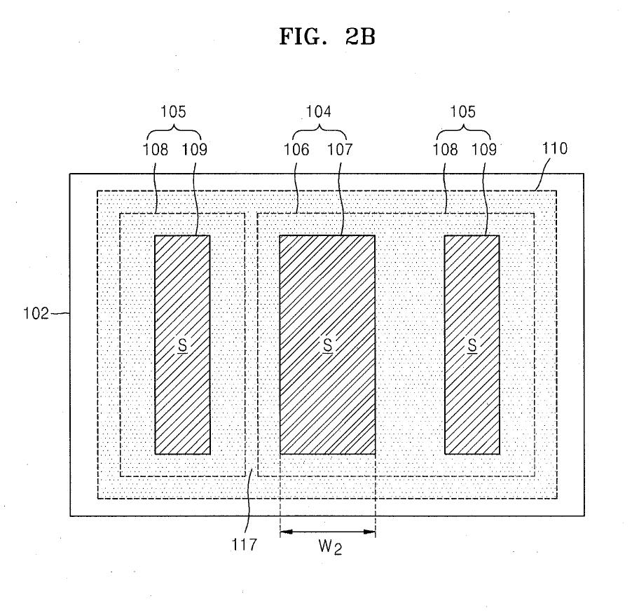

FIG. 1 is a cross-sectional view of a photoelectric conversion module 100, FIG. 2A is a plan view of a light receiving substrate 101 of the photoelectric conversion module 100 and FIG. 2B is a plan view of a counter substrate 102 of the photoelectric conversion module 100.

Referring to FIGS. 1, 2A and 2B, the light receiving substrate 101 and the counter substrate 102 face each other. The light receiving substrate 101 may be formed of a transparent material. The light receiving substrate 101 may be formed of a material having high light transmittance. For example, the light receiving substrate 101 may be formed of glass or a resin film. A resin film is flexible and thus may be appropriate for photoelectric conversion devices that require flexibility. The counter substrate 102 does not require transparency. Nevertheless, the counter substrate 102 may be formed of a transparent material and be configured to receive incident light VL. Thus, incident light may be received on either or both sides of the photoelectric conversion module 100 so as to increase the photoelectric conversion efficiency.

In some embodiments, the counter substrate 102 is formed of the same material as the light receiving substrate 101. In particular, if the photoelectric conversion module 100 is used as a building integrated photovoltaic system (BIPV) installed to a structure such as a window frame of a building, both sides of the photoelectric conversion module 100 may be transparent in order to not block light from flowing into the building.

A plurality of unit photoelectric cells 103 are formed in an inner space between the light receiving substrate 101 and the counter substrate 102. The unit photoelectric cells 103 include optical electrodes 104 and counter electrodes 105 for performing photoelectric conversion. The optical electrodes 104 each include a first transparent conductive film 106 and a semiconductor layer 107. The counter electrodes 105 each include a second transparent conductive film 108 and a catalyst layer 109. Electrolyte layers 110 are interposed between the optical electrodes 104 and the counter electrodes 105. The first transparent conductive films 106 and the second transparent conductive films 108 are each electrically connected to each other either in series or in parallel using leads 111. In the illustrated embodiment, the first transparent conductive films 106 and the second transparent conductive films 108 are each electrically connected to each other in series.

The first transparent conductive films 106 are formed on the inner surface of the light receiving substrate 101. The first transparent conductive films 106 may be formed of a transparent and electrically conductive material. For example, the first transparent conductive films 106 may include a transparent conducting oxide (TCO) such as an indium tin oxide (ITO), a fluorine tin oxide (FTO), or an antimony-doped tin oxide (ATO).

Although not illustrated in FIG. 1, a first grid pattern may be formed on the first transparent conductive films 106. The first grid pattern may be formed to lower electric resistance of the first transparent conductive films 106. The first grid pattern may include a wiring configured to collect electrons generated according to a photoelectric conversion operation. The first grid patter may also provide a low resistance current path. For example, the first grid pattern may be formed of a metal material having excellent electrical conductivity such as gold (Au), silver (Ag), or aluminum (Al). The first grid pattern may be formed in a variety of different patterns. For example, the first grid pattern may be formed in a solid pattern having a specific shape such as square or a meshed pattern having a predetermined opening. When the first grid pattern is formed, a first protection layer may be formed to cover the first grid pattern. The first protection layer may be configured to prevent contact between the first grid pattern and the electrolyte layer 110 and thus be configured to prevent electrodes from being damaged. For example, the first protection layer may be configured to prevent corrosion of the first grid pattern. The first protection layer may be formed of a material that does not react with electrolytes. For example, the first protection layer may be formed of curable resin.

The optical electrodes 104 are configured to function as negative electrodes of the photoelectric conversion module 100 and may have high aperture ratio. The light VL incident through the first transparent conductive films 106 functions as an excitation source of photosensitive dye adsorbed to the semiconductor layers 107. Accordingly, the photoelectric conversion efficiency may be improved by increasing an amount of the light VL incident on the photoelectric conversion module 100. The semiconductor layers 107 may be formed of a metal compound such as Cd, Zn, In, Pb, Mo, W, Sb, Ti, Ag, Mn, Sn, Zr, Sr, Ga, Si, or Cr. The semiconductor layers 107 are configured to adsorb photosensitive dye and thus increase the photoelectric conversion efficiency. For example, the semiconductor layers 107 may be formed by coating paste in which semiconductor particles having a diameter of about 5 nm to about 1000 nm are dispersed on the light receiving substrate 101 on which the first transparent conductive films 106 are formed and then applying predetermined heat or pressure to the paste.

The semiconductor layers 107 are configured to adsorb photosensitive dye that may be excited by the light VL. The photosensitive dye thus adsorbed to the semiconductor layers 107 is configured to absorb the light VL penetrating the light receiving substrate 101 and is incident on the photosensitive dye. Electrons in the photosensitive dye are thus excited into an excitation state from a ground state. The excited electrons are conveyed to a conduction band of the semiconductor layers 107 using electrical junction between the photosensitive dye and the semiconductor layers 107. Excited electrons pass through the semiconductor layers 107 to the first transparent conductive films 106. Then, the excited electrons pass out of the photoelectric conversion module 100 through the first transparent conductive film 106 and thus may constitute a driving current for driving an external circuit.

For example, the photosensitive dye adsorbed to the semiconductor layers 107 includes molecules that absorb visible light in a visible ray band and cause rapid electron transfer to the semiconductor layers 107 when in a light excitation state. The photosensitive dye may be liquid, semisolid gel or solid. For example, the photosensitive dye adsorbed to the semiconductor layers 107 may be ruthenium based photosensitive dye. The semiconductor layers 107 configured to adsorb the photosensitive dye may be formed by immersing the light receiving substrate 101 with formed semiconductor layers in a solution that includes a particular photosensitive dye.

The second transparent conductive films 108 are formed on the inner surface of the counter substrate 102. The second transparent conductive films 108 may be formed of a transparent and electrically conductive material. For example, the second transparent conductive films 108 may include a TCO such as an ITO, a FTO or an ATO. Although not illustrated, a second grid pattern and a second protection layer covering the second grid pattern may be formed on the second transparent conductive films 108. The second grid pattern may be formed in a manner and having a function similar to that of the first grid pattern described previously.

The counter electrodes 105 are configured to function as positive electrodes of the photoelectric conversion module 100 and as a reduction catalyst for providing electrons to the electrolyte layers 110. The photosensitive dye adsorbed to the semiconductor layers 107 may generate excited electrons by absorbing the incident light VL. The excited electrons are passed out of the photoelectric conversion module 100 through the second transparent conductive films 108.

The photosensitive dye from which excited electrons are removed is reduced by collecting electrons from oxidization of the electrolyte layers 110. The oxidized electrolyte layers 110 are reduced by electrons reaching the second transparent conductive films 108 via an external circuit, thereby completing a circuit during operation of the photoelectric conversion module 100.

The catalyst layers 109 may be formed of a material that functions as a reduction catalyst for providing electrons to the electrolyte layers 110. For example, the catalyst layer 109 may be formed of a metal such as platinum (Pt), gold (Au), silver (Ag), copper (Cu), or aluminum (Al), a metal oxide such as tin oxide, or a carbon-based material such as graphite.

A Redox electrolyte including an oxidant and reductant pair may be applied to the electrolyte layers 110. For example, the electrolyte layers 110 may be formed of a solid electrolyte, a gel-type electrolyte or a liquid electrolyte.

The plurality of unit photoelectric cells 103 are arranged in between the light receiving substrate 101 and the counter substrate 102. The unit photoelectric cells 103 are separated by sealants 112. The sealants 112 are configured to seal the electrolyte layer 110 and prevent an electrolyte of the electrolyte layers 110 from leaking out of the photoelectric conversion module 100. In the illustrated embodiment, the unit photoelectric cells 103 include three unit photoelectric cells S, for example, a first unit photoelectric cell 113, a second unit photoelectric cell 114 and a third unit photoelectric cell 115. It will be understood by one of ordinary skill in the art that the number of unit photoelectric cells 103 may vary according to the design of the photoelectric conversion module 100.

Here, the optical electrodes 104 and the counter electrodes 105 are alternately arranged on the light receiving substrate 101. The counter electrodes 105 and the optical electrodes 104 are alternately arranged on the counter substrate 102. The counter electrodes 105 and the optical electrodes 104 alternately arranged on the counter substrate 102 face the optical electrodes 104 and the counter electrodes 105 alternately arranged on the light receiving substrate 101, respectively.

Also, transparent conductive films on the light receiving substrate 101 of two adjacent unit photoelectric cells 103, that is, the first transparent conductive film 106 on the light receiving substrate 101 of one unit photoelectric cell 103 and the second transparent conductive film 108 on the light receiving substrate 101 of another unit photoelectric cell 103, are electrically connected to each other. In addition, the first transparent conductive film 106 and the second transparent conductive film 108 that correspond to the light receiving substrate 101 of a pair of unit photoelectric cells 103 are separated from those of another pair of unit photoelectric cells 103 by a first scribe line 116.

In the illustrated embodiment, the semiconductor layer 107 of the first unit photoelectric cell 113 and the catalyst layer 109 of the second unit photoelectric cell 114 are formed on the first transparent conductive film 106 of the first unit photoelectric cell 113 and the second transparent conductive film 108 of the second unit photoelectric cell 114, respectively. The first transparent conductive film 106 of the first unit photoelectric cell 113 and the second transparent conductive film 108 of the second unit photoelectric cell 114 are electrically connected to each other.

In addition, transparent conductive films on the counter substrate 102 of two adjacent unit photoelectric cells 103 are arranged alternately with transparent conductive films on the light receiving substrate 101 of the two adjacent unit photoelectric cells 103. That is, the first transparent conductive film 106 on the counter substrate 102 of one unit photoelectric cell 103 and the second transparent conductive film 108 on the counter substrate 102 of another unit photoelectric cell 103, are electrically connected to each other on the counter substrate 102 formed facing the light receiving substrate 101 in a perpendicular direction. In addition, the first transparent conductive film 106 and the second transparent conductive film 108 that correspond to the counter substrate 102 of a pair of unit photoelectric cells 103 are separated from those of another pair of unit photoelectric cells 103 by a second scribe line 117.

In the illustrated embodiment, the semiconductor layer 107 of the second unit photoelectric cell 114 and the catalyst layer 109 of the third unit photoelectric cell 115 are formed on the first transparent conductive film 106 of the second unit photoelectric cell 114 and the second transparent conductive film 108 of the third unit photoelectric cell 115, respectively. The first transparent conductive film 106 of the second unit photoelectric cell 114 and the second transparent conductive film 108 of the third unit photoelectric cell 115 are electrically connected to each other.

In the illustrated embodiment, the first scribe lines 116 and the second scribe lines 117 are arranged alternately with each other to separate unit photoelectric cells 103. Accordingly, the photoelectric conversion module 100 may be configured so electrons flow through the photoelectric conversion module 100 in a manner as follows (where arrows indicate direction of electron flow): the second transparent conductive film 108 of one unit photoelectric cell (for example, the first unit photoelectric cell 113)→the catalyst layer 109 of the one unit photoelectric cell→the electrolyte layer 110 of the one unit photoelectric cell→the semiconductor layer 107 of the one unit photoelectric cell→the first transparent conductive film 106 of the one unit photoelectric cell→the second transparent conductive film 108 of an adjacent unit photoelectric cell (for example, the second unit photoelectric cell 114)→the catalyst layer 109 of the adjacent unit photoelectric cell→the electrolyte layer 110 of the adjacent unit photoelectric cell→the semiconductor layer 107 of the adjacent unit photoelectric cell→the first transparent conductive film 106 of the adjacent unit photoelectric cell → . . . .

The electricity generation efficiency of the light receiving substrate 101 on which the light VL (shown as broken arrows), is incident may be higher than that of the counter substrate 102. For example, if the electricity generation efficiency of the light receiving substrate 101 is approximately 100%, the electricity generation efficiency of the counter substrate 102 may be approximately 70%.

The photovoltaic power generation occurs substantially via the optical electrodes 104, which include the semiconductor layers 107. However, the light VL may be substantially blocked by the catalyst layers 109 due to type material used to form the catalyst layers 109. This may significantly decrease the overall quantity of light. Further, the electricity generation efficiency may further decrease when the light also passes through the electrolyte layer 110.

Accordingly, to improve the electricity generation efficiency, a width of each of the semiconductor layers 107 on the light receiving substrate 101 a width of each of the semiconductor layers 107 on the counter substrate 102 are formed to be asymmetric with each other. In some embodiments, a width W2 of semiconductor layers 107 on the counter substrate 102 is greater than a width W1 of semiconductor layers 107 on the light receiving substrate 101. In some embodiments, the width W2 of the semiconductor layers 107 on the counter substrate 102 may be greater than the width W1 of the semiconductor layers 107 on the light receiving substrate 101, but be less than twice the width W1 of the semiconductor layers 107 on the light receiving substrate 101. When the width W2 of the semiconductor layers 107 on the counter substrate 102 is greater than twice the width W1 of the semiconductor layers 107 on the light receiving substrate 101, resistance is significantly increased and thus a fill factor may be damaged. Accordingly, power of the photoelectric conversion module 100 may be reduced.

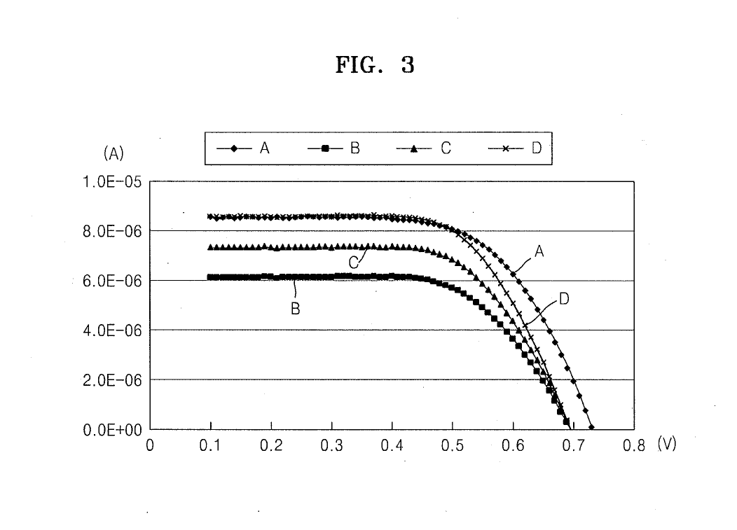

FIG. 3 is a graph showing electricity generation efficiency of the photoelectric conversion module 100 of FIG. 1 measured by varying a width of the semiconductor layers 107 according to an experiment. Here, an X-axis indicates a voltage V and a Y-axis indicates a current A. Also, a width of the semiconductor layers 107 on the light receiving substrate 101 to which the light LV is incident is about 5 mm (A), and a width of the semiconductor layers 107 on the counter substrate 102 is about 5 mm (B), 6 mm (C), and 7 mm (D) for three different tests, respectively.

Referring to FIG. 3, as the width of the semiconductor layers 107 on the counter substrate 102 increases from 5 mm (B) to 7 mm (D), a current value increases and thus the current value of the counter substrate 102 may be approximately be the same as the current value of the light receiving substrate 101. That is, if the width of the semiconductor layers 107 on the counter substrate 102 is greater by about 40% the width of the semiconductor layers 107 on the light receiving substrate 101, an optimum current value may be obtained.

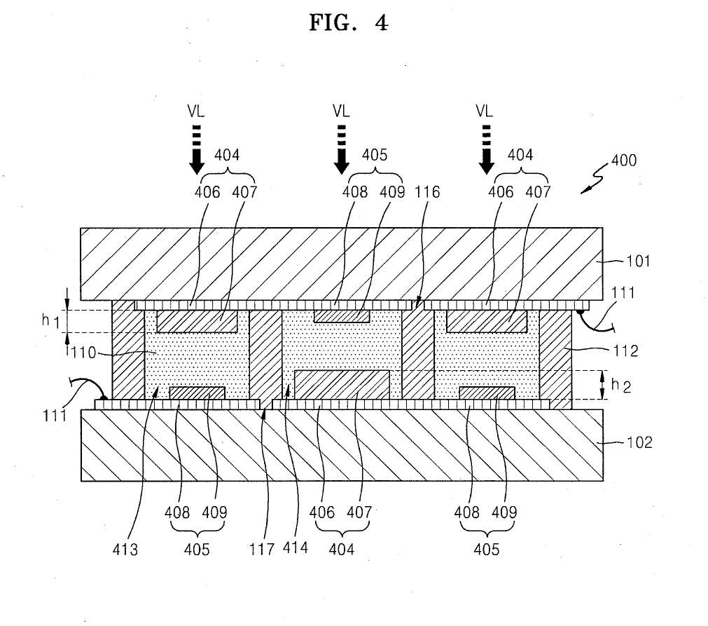

FIG. 4 is a cross-sectional view of a photoelectric conversion module 400 according to another embodiment of the present disclosure. Like reference numerals in the drawings described above denote like elements. A thickness of semiconductor layers 407 vary in the photoelectric conversion module 400, whereas the widths of the semiconductor layers 107 vary in the photoelectric conversion module 100 of FIG. 1.

Referring to FIG. 4, optical electrodes 404 and counter electrodes 405 are alternately arranged on the light receiving substrate 101. The counter electrodes 405 and the optical electrodes 404 are alternately arranged on the counter substrate 102. The counter electrodes 405 and the optical electrodes 404 alternately arranged on the counter substrate 102 face the optical electrodes 404 and the counter electrodes 405 alternately arranged on the light receiving substrate 101, respectively.

Also, one semiconductor layer 407 on the light receiving substrate 101 of one unit photoelectric cell 413 and one catalyst layer 409 on the light receiving substrate 101 of an adjacent unit photoelectric cell 414 are formed on a first transparent conductive film 406 on the light receiving substrate 101 of the one unit photoelectric cell 413 and a second transparent conductive film 408 on the light receiving substrate 101 of the adjacent unit photoelectric cell 414, respectively. The first transparent conductive film 406 on the light receiving substrate 101 of the one unit photoelectric cell 413 and the second transparent conductive film 408 on the light receiving substrate 101 of the adjacent unit photoelectric cell 414 are electrically connected to each other. In the one unit photoelectric cell 413, a catalyst layer 409 is formed facing the light receiving substrate 101 in a perpendicular direction on a transparent conductive film 408 on the counter substrate 102. In the adjacent unit photoelectric cell 414, a semiconductor layer 407 is formed facing the light receiving substrate 101 in a perpendicular direction on a first transparent conductive film 406 on the counter substrate 102. The catalyst layer 409 formed facing the light receiving substrate 101 in a perpendicular direction on a transparent conductive film 408 and the semiconductor layer 407 formed facing the light receiving substrate 101 in a perpendicular direction on a first transparent conductive film 406 are formed to alternate with each other on the counter substrate 102. The first transparent conductive film 406 on the counter substrate 102 of the one unit photoelectric cell 413 and the second transparent conductive film 408 on the counter substrate 102 of the adjacent unit photoelectric cell 414 are electrically connected to each other.

Here, a height of the semiconductor layers 407 on the light receiving substrate 101 to which light is incident and a height of the semiconductor layers 407 on the counter substrate 102 on the counter substrate 102 are formed to be asymmetric with each other. In some embodiments, a height h2 of the semiconductor layers 407 on the counter substrate 102 is greater than a height h1 of the semiconductor layers 407 on the light receiving substrate 101. For example, if widths of the semiconductor layers 407 are the same with respect to the light receiving substrate 101 as with respect to the counter substrate 102, the height h1 of the semiconductor layers 407 on the light receiving substrate 101 may be between about 8 μm and about 25 μm. In some embodiments, the height h1 of the semiconductor layers 407 on the light receiving substrate 101 may be between about 13 and about 15 μm.

On the other hand, the height h2 of the semiconductor layers 407 on the counter substrate 102 may be greater than the height hl of the semiconductor layers 407 on the light receiving substrate 101, but may be less than or equal to a maximum height, for example, ± about 5 μm, of the semiconductor layers 407 on the light receiving substrate 101. Then, the electricity generation efficiency of the photoelectric conversion module 400 may be improved.

The size of the semiconductor layers 407 on the counter substrate 102 with respect to the size of the semiconductor layers 407 on the light receiving substrate 101 is not limited to being varied with respect to only a width or a thickness and instead the thickness and the width of the semiconductor layers 407 may be varied to form semiconductor layers that are asymmetric with each other on the light receiving substrate 101 and the counter substrate 102.

As described above, according to the one or more of the above embodiments of the present disclosure, widths or heights of optical electrodes each including a semiconductor layer are formed to be asymmetric with each other in a photoelectric conversion module and thus the electricity generation efficiency may be improved.

While the present invention has been described in connection with certain exemplary embodiments, it will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Thus, while the present disclosure has described certain exemplary embodiments, it is to be understood that the disclosure is not limited to the disclosed embodiments, but, on the contrary, is intended to cover various modifications and equivalent arrangements included within the spirit and scope of the appended claims, and equivalents thereof.

What is claimed is:

1. A photoelectric conversion module, comprising:
a light receiving substrate and a counter substrate facing each other; and
a first unit photoelectric cell and a second unit photoelectric cell formed between the light receiving substrate and the counter substrate,
wherein the first unit photoelectric cell comprises a first optical electrode formed on the light receiving substrate and a first counter electrode formed on the counter substrate,
wherein a second unit photoelectric cell comprises a second optical electrode formed on the counter substrate and a second counter electrode formed on the light receiving substrate,
wherein the first optical electrode comprises a first semiconductor layer,
wherein the second optical electrode comprises a second semiconductor layer, and
wherein a first width of the first semiconductor layer is asymmetric to a second width of the second semiconductor layer.

2. The photoelectric conversion module of claim 1, wherein a first electrolyte layer is positioned between the first optical electrode and the first counter electrode.

3. The photoelectric conversion module of claim 1, wherein a second electrolyte layer is positioned between the second optical electrode and the second counter electrode.

4. The photoelectric conversion module of claim 1, wherein the first optical electrode further comprises a first transparent conductive film.

5. The photoelectric conversion module of claim 4, wherein the first counter electrode comprises a second transparent conductive film and a first catalyst layer.

6. The photoelectric conversion module of claim 5, wherein the second optical electrode further comprises a third transparent conductive film.

7. The photoelectric conversion module of claim 6, wherein the second counter electrode comprises a fourth transparent conductive film and a second catalyst layer.

8. The photoelectric conversion module of claim 7, wherein the first transparent conductive film, the second transparent conductive film, the third transparent conductive film and the fourth transparent conductive film are electrically connected to leads.

9. The photoelectric conversion module of claim 1, wherein the first width is less than the second width.

10. The photoelectric conversion module of claim 9, wherein the second width is less than about twice the first width.

11. The photoelectric conversion module of claim 1, wherein the second width is less than the first width.

12. The photoelectric conversion module of claim 11, wherein the first width is less than about twice the second width.

13. The photoelectric conversion module of claim 1, wherein the first width and the second width are measured in a direction substantially parallel to the surface of the light receiving substrate and the counter substrate, respectively.

14. The photoelectric conversion module of claim 1, wherein a first height of the first semiconductor layer is asymmetric to a second height of the second semiconductor layer.

15. The photoelectric conversion module of claim 14, wherein the first height is measured in a direction substantially normal to the surface of the light receiving substrate and wherein the second height is measured in a direction substantially normal to the surface of the counter substrate.

16. The photoelectric conversion module of claim 1, wherein the first unit photoelectric cell and the second unit photoelectric cell are separated by a sealant.

17. The photoelectric conversion module of claim 16, wherein the sealant comprises a first scribe line.

18. A photoelectric conversion module, comprising:
a light receiving substrate and a counter substrate facing each other; and
a first unit photoelectric cell and a second unit photoelectric cell formed between the light receiving substrate and the counter substrate,
wherein the first unit photoelectric cell comprises a first optical electrode formed on the light receiving substrate and a first counter electrode formed on the counter substrate,
wherein a second unit photoelectric cell comprises a second optical electrode formed on the counter substrate and a second counter electrode formed on the light receiving substrate,
wherein the first optical electrode comprises a first semiconductor layer,
wherein the second optical electrode comprises a second semiconductor layer,
wherein a first height of the first semiconductor layer is asymmetric to a second height of the second semiconductor layer,
wherein the first height is measured in a direction substantially normal to the surface of the light receiving substrate, and
wherein the second height is measured in a direction substantially normal to the surface of the counter substrate.

19. The photoelectric conversion module of claim 1, wherein the first optical electrode of the first unit photoelectric cell and second counter electrode of the second unit photoelectric cell are alternately arranged on the light receiving substrate, wherein the first counter electrode of the first unit photoelectric cell and second optical electrodes of the second unit photoelectric cells are alternately arranged on the counter substrate, and the first counter electrode of the first unit photoelectric cells and the second optical electrode of the second unit photoelectric cells arranged on the counter substrate are formed to face the first optical electrode of the first unit photoelectric cell and the second counter electrode of the second unit photoelectric cell arranged on the light receiving substrate, respectively, in a perpendicular direction to the surface of the light receiving substrate and the surface of the counter substrate.

20. The photoelectric conversion module of claim 19, wherein the first optical electrode comprises a first transparent conductive film, wherein the first counter electrode comprises a second transparent conductive film, wherein the second optical electrode comprises a third transparent conductive film, and wherein the second counter electrode comprises a fourth transparent conductive film.

21. The photoelectric conversion module of claim 20, wherein the first transparent conductive film and the fourth transparent conductive film are electrically connected to each other on the light receiving substrate, and wherein the first transparent conductive film and the fourth transparent conductive film are separated from each other by a first scribe line between a pair of the first and the second unit photoelectric cells and another adjacent pair of the first and the second unit photoelectric cells.

22. The photoelectric conversion module of claim 21, wherein the second transparent conductive film and the third transparent conductive film are electrically connected to each other on the counter substrate to respectively alternate with the first transparent conductive film and the fourth transparent conductive film, and the second transparent conductive film and the third transparent conductive film are separated from each other by a second scribe line between the pair of the first and the second unit photoelectric cells and the another adjacent pair of the first and the second unit photoelectric cells.

23. The photoelectric conversion module of claim 19, wherein the first height is less than the second height.
